(19) United States
(12) Patent Application Publication
(10) Pub. No.: US 2025/0223452 A1
(43) Pub. Date: Jul. 10, 2025

(54) SUPERCONDUCTING WS2-BASED NANOSHEET INK

(71) Applicant: The Trustees of Princeton University, Princeton, NJ (US)

(72) Inventors: Leslie M. SCHOOP, Princeton, NJ (US); Xiaoyu SONG, Plainsboro, NJ (US)

(73) Assignee: The Trustees of Princeton University, Princeton, NJ (US)

(21) Appl. No.: 18/853,565

(22) PCT Filed: Apr. 3, 2023
(86) PCT No.: PCT/US2023/017307

§ 371 Date: Oct. 2, 2024

Related U.S. Application Data
(60) Provisional application No. 63/327,103, filed on Apr. 4, 2022.

(51) Int. Cl. C09D 11/037; B41J 2/175; B41M 5/00; B41M 7/00; C09D 11/322; C09D 11/52; H05K 1/09; H05K 3/12

(52) U.S. Cl. CPC C09D 11/037; B41J 2/17503; B41M 5/0047; B41M 7/0081; C09D 11/322; C09D 11/52; H05K 1/092; H05K 3/12

(57) ABSTRACT

An ink may be provided that includes a two-dimensional WS₂ nanosheet and an organic solvent, such as water, and may be free of protective molecules and surfactants. Circuits may be provided that include this ink disposed onto a surface of a substrate (such as a flexible substrate) in various patterns, including, e.g., a superconducting qubit. The ink may be formed by sonicating, then centrifuging at a first speed, a sulfuric acid-KxWS2 solution, where x=0.3˜0.7, removing any supernatant from the centrifuged first suspension and replacing with water and sonicating the resulting WS2-water suspension, then centrifuging the result at a speed slower than the first speed, and using an upper portion of the resulting suspension.

### CROSS-REFERENCE TO RELATED APPLICATIONS

The present application claims priority to U.S. Provisional Patent App. No. 63/327,103, filed Apr. 4, 2022, the contents of which are incorporated by reference herein in its entirety.

### STATEMENT REGARDING FEDERALLY SPONSORED RESEARCH OR DEVELOPMENT

This invention was made with government support under Grant No. DMR-2011750 awarded by the National Science Foundation and Grant No. N00014-21-1-2733 awarded by the Department of Defense. The government has certain rights in the invention.

### TECHNICAL FIELD

The present application is drawn to superconducting ink, and WS₂-based nanosheet ink in particular.

### BACKGROUND

Two-dimensional (2D) materials have inspired research in both, fundamental and applied areas, such as electronics, catalysis, or energy storage. Among the synthetic strategies to obtain high-quality 2D materials, liquid-phase chemical exfoliation is attractive as it is capable to delaminate a large variety of parent compounds and is not limited to van der Waals (vdW) layered crystals. In addition, chemical exfoliation can yield large quantities of free-standing 2D nanosheets, possibly sufficient for industrial-scale production.

One particular class of layered materials. Transition metal dichalcogenides (TMD), has been studied widely as they enable diverse applications that range from catalysis and batteries to electronics. Furthermore, TMDs are highly tunable as they appear in various polymorphs with fundamentally different properties. For example, WS₂ naturally forms a semiconducting 2H structure which can be directly exfoliated into 1H-WS₂ monolayers by direct sonication in various organic solvents. Both the bulk and the 2D sheets are semiconducting and 1H-WS₂ nanosheets are used as catalysts for photocatalytic hydrogen evolution, as well as transistors.

Recently, a new phase of WS₂, the superconducting 2M-WS₂ phase, which consists of distorted 1T′-WS₂ layers in a two-layer unit cell, has been synthesized by oxidizing K_{0.7}WS₂ with either K₂Cr₂O₇ in diluted H₂SO₄ or I₂ in acetonitrile. This new 2M-WS₂ phase has the highest superconducting transition temperature (T_{c}) among the TMDs.

2M-WS₂ can be mechanically exfoliated down to the monolayer limit in its structural 1T′-WS₂ unit. The mechanically exfoliated 1T′-WS₂ monolayer has been reported to be metallic; its resistivity drops at 5.7 K, but does not reach zero. It is well established that metallic WS₂ monolayer nanosheets can be synthesized via Li intercalation of 2H-WS₂ and subsequent sonication in water, but these nanosheets are never to 100% in the 1T′ phase, and usually have many defects.

In general, high-quality 2D superconducting monolayers suspensions are scarce. There are only a few reports of such, and their superconducting transition temperatures (T_{c}) are relatively low. For example, restacked-TaS₂ nanosheets have a T_{c} of 3 K, defect-enhanced 2H-TaS₂ monolayers have a T_{c} of up to 3.61 K, 1T-MoS₂ nanosheets have a T_{c} of 4.6 K, and recently a printed electrochemically exfoliated NbSe₂ nanosheets film has a T_{c} of 6.8 K.

Out of these, only the last material has been shown to be usable as a printable ink. In that case however, protective molecules are necessary to stabilize the ink, as NbSe₂ is relatively air-sensitive.

### BRIEF SUMMARY

Various deficiencies in the prior art are addressed below by the disclosed compositions of matter and techniques.

In various aspects, an ink, e.g., for use in creating printable and flexible electronics may be provided. The ink may include a two-dimensional WS₂ nanosheet and a solvent. The ink may be free of protective molecules and/or surfactants. The solvent may be an organic solvent, and may be water. The ink may be maintained at or below 20° C. In some embodiments, the ink may be maintained at or below 7.3 K.

In various aspects, an electronic circuit may be provided. The electronic circuit may include a substrate and ink as disclosed herein disposed or deposited on a first surface of the substrate to form a pattern. The pattern may comprise a superconductive qubit. The pattern may include a first portion that is a superconducting portion, and a second portion that has been treated to form a semiconducting portion. The substrate may be flexible. The ink may be maintained at or below 20° C. In some embodiments, the electronic circuit may be maintained at or below 7.3 K.

In various aspects, an ink cartridge may be provided. The ink cartridge may include ink as disclosed herein, and a housing configured to hold the ink.

In various aspects, a method for forming a device may be provided. The method may include providing an ink as disclosed herein, and depositing the ink (e.g., with a 3D printer) onto a first surface of a substrate, e.g., to form one or more electronic circuits. A portion of the ink that was deposited may be treated to form a semiconducting portion. The treatment may include heating the ink with a laser or e-beam. The method may include controlling a temperature of the deposited ink to be below 7.3 K.

In various aspects, a method for manufacturing an ink may be provided. The method may include forming a first suspension by sonicating KₓWS₂ and a sulfuric acid solution, where X=0.3˜0.7. The first suspension may be centrifuged at a first speed. A WS₂-water suspension may be formed by removing any supernatant from the centrifuged first suspension and replacing with water, then sonicating the WS₂-water suspension. A water-based ink may be formed by centrifuging the WS₂-water suspension at a second speed, the second speed being less than the first speed, and utilizing an upper portion of a resulting suspension. In some embodiments. A WS₂-alternate solvent ink may be formed by centrifuging the water-based ink in the presence of an alternate solvent at a third speed, the third speed being higher than the first speed.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF FIGURES

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is an illustration of the (010) plane as a side-view of monolayer 1T′-WS₂.

FIG. 2 is an illustration of an electronic device.

FIG. 3 is an illustration of the top view of a superconducting qubit.

FIG. 4 is an illustration of an ink cartridge.

FIG. 5 is a simplified flowchart for a method for producing an electronic device.

FIG. 6 is a simplified flowchart for a method for producing an ink.

FIG. 7A is a graph showing resistance versus temperature data from 300 K to 1.8 K for a freshly printed 1T′-WS₂ film without any external magnetic field. For the tested device, RRR=R_{285K}/R_{8K}=3.

FIG. 7B is a graph showing the superconducting transition region for the device tested in FIG. 7A.

FIG. 8A is a graph showing angle-dependent resistance data of the printed 1T′-WS₂ device measured from 2 K to 6 K with a 9 T external magnetic field when the field is rotated from perpendicular to parallel to the device plane.

FIG. 8B is a graph showing angle-dependence of the resistance measured at 2 K with a 3 T to 9 T external magnetic field.

FIG. 8C is an illustration showing the experimental configuration where the magnetic field is perpendicular to the printed device plane at ϕ=0° and φ=360°).

FIGS. 9A and 9B are graphs showing temperature-dependent resistance (R-T) of a printed 1T′-WS₂ film, measured under external magnetic fields ranging from (T to 9 T, applied perpendicular (9A) or parallel (9B) to the device plane.

FIGS. 9C and 9D are graphs showing isotherms of the printed 1T′-WS₂ film in FIGS. 9A and 9B from 2 K to 10 K, measured with an external magnetic field that is applied perpendicular (9C) or parallel (9D) to the device plane.

FIG. 9E is a graph showing upper critical field H_{c2} versus T_{c} plot for both μ₀H^{⊥} and μ₀H^{∥}, where the experimental data are fitted using Ginzburg-Landau (GL) theory.

FIG. 9F is a graph showing current (I) vs. voltage (V) curves of the printed 1T′-WS₂ film measured from 2 K to 8 K with an AC current of frequency 24.41 Hz.

FIG. 9G is a graph showing I-V curves measured at 2 K with different ac current frequencies.

FIG. 9H is a graph showing temperature-dependent magnetic susceptibility of dried 1T′-WS₂ nanosheet-powder collected from the ink: the inset is a graph showing magnetic field-dependent magnetization of the same sample measured at 1.8 K.

FIGS. 10A and 10B are graphs representing statistical analyses of thickness/layer numbers (10A) and lateral size (10B) of 1T′-WS₂ nanosheets within ink. It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term. “or.” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

In various aspects, an ink, e.g., for use in creating printable and flexible electronics may be provided. The ink may include a two-dimensional WS₂ nanosheet and a solvent.

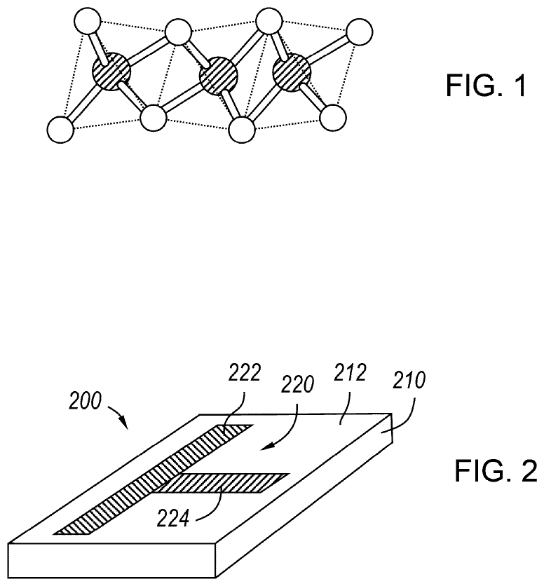

The two-dimensional WS₂ nanosheet should include WS₂ in its 1T′-WS₂ form. A side view of the general structure of monolayer 1T′-WS₂ can be seen in FIG. 1. In some embodiments, 100% or more of the WS₂ in the ink is in the 1T′-WS₂ form. In some embodiments, 99% or more of the WS₂ in the ink is in the 1T′-WS₂ form. In some embodiments, 98% or more of the WS₂ in the ink is in the 1T′-WS₂ form. In some embodiments. 97% or more of the WS₂ in the ink is in the 1T′-WS₂ form. In some embodiments, 96% or more of the WS₂ in the ink is in the 1T′-WS₂ form. In some embodiments, 95% or more of the WS₂ in the ink is in the 1T′-WS₂ form.

The solvent may be an organic solvent. In some embodiments, the organic solvent may be water. In some embodiments, the solvent may be miscible in water. In some embodiments, a C₂-C₄ monoalcohol, such as ethanol (ethyl alcohol) or isopropanol (isopropyl alcohol). The solvent may be an amine. The amine may be a C6-30 primary amine such as hexadecylamine. The amine may be a C6-30 secondary amine such as dioctylamine. The amine may be a C6-40 tertiary amine such as trioctylamine. The solvent may be an aliphatic hydrocarbon. The aliphatic hydrocarbon may be an alkane, such as hexadecane. The solvent may be an aromatic hydrocarbon. The aromatic hydrocarbon may be a C6-C30 aromatic hydrocarbon such as phenyldodecane. The solvent may be a cyclic ether, such as tetrahydrofuran (THF). The solvent may be a nitrile, such as acetonitrile.

Other non-limiting examples of the solvent include, e.g., M-methyl pyrrolidone (NMP), N-ethyl-pyrrolidone (NEP), Cyclohexylpyrrolidone (CHP), Cyclopentanone (CPO), Cyclohexanone (CHO), N-formyl piperidine (NFP), Vinyl pyrrolidone (NVP), 1,3-Dimethyl-2-imidazolidinone (DMEU), Dimethylformamide (DMF), Dimethylacetamide (DMA), Dimethyl sulfoxide (DMSO), Chloroform, Isopropylalcohol (IPA). Cholobenzene, 1-Octyl-2-pyrrolidone (N8P), 1-3 dioxolane, Ethyl acetate. Quinoline, Benzaldehyde, Ethanolamine, Diethyl phthalate, N-Dodecyl-2-pyrrolidone (N12P), Pyridine, Dimethyl phthalate, formamide, or vinyl acetate.

The ink may be free of protective molecules. The protective molecules are those that are added to “protect” the nanosheets from destabilizing when exposed to certain conditions (such as air). As used herein, the term “free of [some material]” indicates the material is either not present, or present at levels below those required to provide a functional benefit. This may be at amounts of 0.1% or less by weight or 0.01% or less by weight of the ink.

The ink may include a surfactant. As used herein, the term “surfactant” refers to an organic chemical that, when added to a liquid, changes the properties of that liquid at a surface. Such surfactants may be used, e.g., as wetting agents, and may also be used for increasing stability of the ink. Non-limiting examples include carboxylic acids (such as oleic acid or acetic acid) and thiols (such as octanethiol or hexanethiol). Preferably, the ink may be free of surfactants.

The ink may be stable at or below the boiling point of water (e.g., 100° C. at 760 mm Hg). The two-dimensional WS₂ nanosheet may be stable below at least 150° C. In some embodiments, the ink may be maintained at or below 20° C. In some embodiments, the ink may be maintained at or below 7.3 K.

In various aspects, an electronic circuit may be provided. Referring to FIG. 2, the electronic circuit 200 may include a substrate 210 and ink as disclosed herein disposed or deposited on a first surface 212 of the substrate.

In some embodiments, the substrate may include any known material used for a printed circuit board (PCB). In some embodiments, the substrate may be rigid. In some embodiments, the substrate may be flexible. The substrate may be a flexible dielectric substrate, and may be composed of a polymer such as a polyimide, a polyether ether ketone (PEEK), or a polyester. Non-limiting examples of materials used to form the substrate include polyethylene terephthalate (PET), poly butylene terephthalate (PBT), polysilane, polysiloxane, polysilazane, polycarbosilane, polyacrylate, polymethacrylate, polymethylacrylate, polymethylmetacrylate, polyethylacrylate, polyethylmetacrylate, cycloolefin copolymer, (COC), cycloolefin polymer (COP), polyethylene (PE), polypropylene (PP), polyimide (PI), polymethylmethacrylate (PMMA), polystyrene (PS), polyacetal (POM), polyether ether ketone (PEEK), polyester sulfone (PES), polytetrafluoroethylene (PTFE), polyvinyl chloride (PVC), polycarbonate (PC), polyvinylidene fluoride (PVDF), perfluoroalkyl polymer (PFA), styrene acrylic nitrile copolymer (SAN), or any combination thereof.

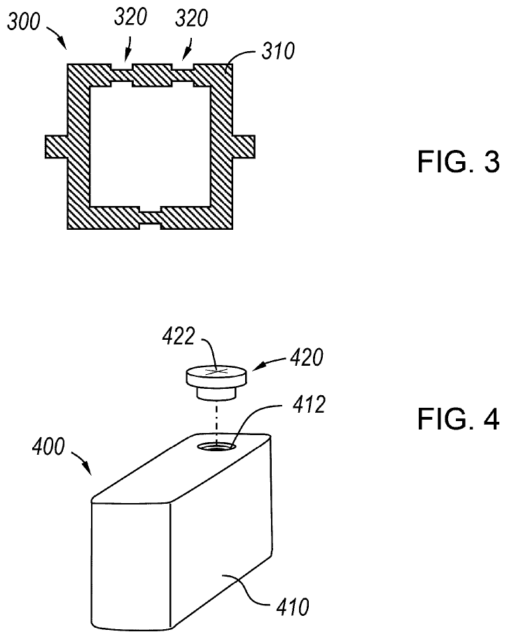

The ink disposed on the substrate may form a pattern 220, which may define, e.g., one or more circuits. Such patterns are well known in the art, and any appropriate pattern may be utilized here. For example, the pattern may include a superconductive qubit. Referring to FIG. 3, a non-limiting example of such a qubit 230 can be seen, where the ink 232 is deposited to form a loop pattern, including one or more Josephson junctions 234. Such loops and junctions are well known in the art, and other variants may be utilized, that may include other features, including capacitors, etc.

Referring to FIG. 2, at least a first portion 222 of the pattern may be superconducting. In some embodiments, a second portion 224 may be deposited in a superconducting form, but the may later be treated to be semiconducting, e.g., by changing its form from the 1T′-WS₂ form to a 1H-WS₂ or 1T-WS₂ form. For example, after depositing, the second portion may be heated with a laser or e-beam.

The ink may be maintained at or below 20° C. In some embodiments, the electronic circuit may be maintained at or below 7.3 K.

In various aspects, an ink cartridge may be provided. Referring to FIG. 4, the ink cartridge 400 may a housing 410 configured to hold the ink, with the ink being disposed within an internal cavity defined by the housing. An opening 412 may be included to allow the ink to be added or removed. The opening may be closed, e.g., by a cap or seal 420. In some embodiments, the cap or seal may include a portion 422 that has been pre-cut to allow a needle or nozzle to be inserted through the cap or seal, but to prevent ink from escaping when the needle or nozzle is not present. In some embodiments, the cap or seal may be a film, such as a metallized film. In some embodiments, the cap or seal may be composed of one or more polymers.

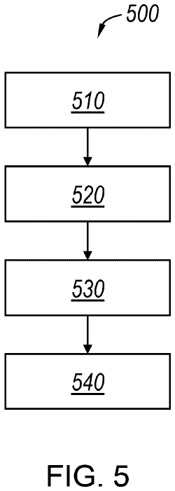

In various aspects, a method for forming a device may be provided. Referring to FIG. 5, the method may include providing 510 an ink as disclosed herein and depositing 520 the ink onto a first surface of a substrate, e.g., to form one or more electronic circuits. Any appropriate deposition technique may be utilized, including, e.g., via a 3D printer or inkjet printer, screen printing, gravure, flexography, etc. Such deposition techniques are well-known in the art.

A portion of the ink that was deposited may be treated 530 to form a semiconducting portion. The treatment may include heating the ink with a laser or e-beam. The method may include controlling 540 a temperature of the deposited ink to be below 7.3 K. It should be understood that although FIG. 5 shows the temperature-controlling step as occurring as a last step, controlling the temperature may occur at any or all stages of this method. For example, the temperature may be controlled to be below 7.3 K prior to the deposition of the ink.

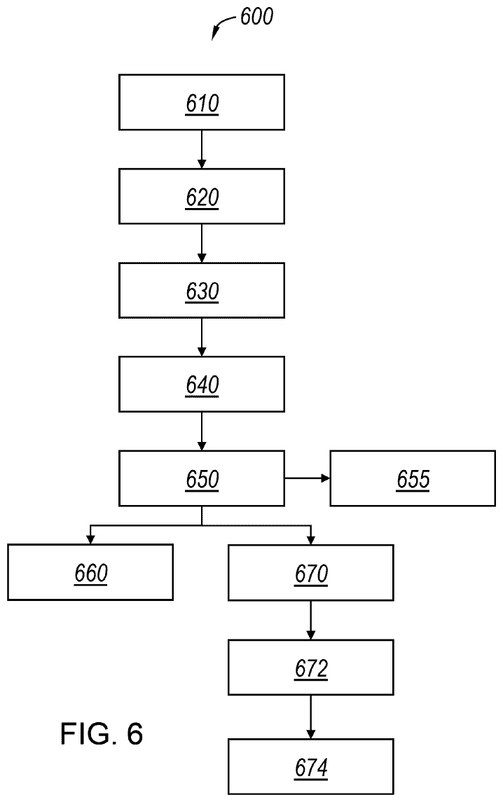

In various aspects, a method for manufacturing an ink may be provided. The synthesis is highly repeatable and reproducible. Referring to FIG. 6, the method 600 may include forming 610 a first suspension by sonicating KₓWS₂ and a sulfuric acid solution, where x=0.3˜0.7. In some embodiments, the sonication may occur, e.g., at a relatively low power (e.g., less than 70 W of power). In some embodiments, the sonication may occur for, e.g., 30 min-2 hours.

The first suspension may be centrifuged 620 at a first speed. For example, in some embodiments, the first suspension may be centrifuged at a speed of 8,000-20,000 rpm. In some embodiments, this centrifuging step may be done for 5-60 minutes. In some embodiments, this centrifuging step may occur at sub-ambient temperatures, such as at 1-10° C.

A WS₂-water suspension may be formed 630 by removing any supernatant from the centrifuged first suspension and replacing with water.

The WS₂-water suspension may then be sonicated 640. In some embodiments, the sonication may occur, e.g., at a relatively low power (e.g., less than 70 W of power). In some embodiments, the sonication may occur for, e.g., 30 min-2 hours.

A water-based ink may be formed by centrifuging 650 the WS₂-water suspension at a second speed, the second speed being less than the first speed, and utilizing 655 an upper portion of a resulting suspension. For example, in some embodiments, the WS₂-water suspension may be centrifuged at a speed of 1,000-5,000 rpm. In some embodiments, this centrifuging step may be done for 5-60 minutes. In some embodiments, this centrifuging step may occur at sub-ambient temperatures, such as at 1-10° C.

A WS₂-alternate solvent ink may be formed by centrifuging 660 the water-based ink in the presence of an alternate solvent at a third speed, the third speed being higher than the first speed. The alternative solvent may be, e.g., an organic solvent as disclosed herein. In some embodiments, this step may occur at speeds of 11,000-30,000 rpm (again, provided the speed is greater than the first speed). In some embodiments, this centrifuging step may be done for 5-60 minutes. In some embodiments, this centrifuging step may occur at sub-ambient temperatures, such as at 1-10° C.

A WS₂-alternate solvent ink may be formed by separating 670 the nanosheets from the solvent by centrifuging the water-based ink at a third speed, the third speed being higher than the first speed. In some embodiments, this step may occur at speeds of 11,000-30,000 rpm (again, provided the speed is greater than the first speed). In some embodiments, this centrifuging step may be done for 5-60 minutes. In some embodiments, this centrifuging step may occur at sub-ambient temperatures, such as at 1-10° C. The nanosheets are then dried 672, and the dried nanosheets may then be sonicated 674 in an alternate solution, which may be, e.g., an organic solvent as disclosed herein. In some embodiments, the sonication may occur, e.g., at a relatively low power (e.g., less than 70 W of power). In some embodiments, the sonication may occur for, e.g., 30 min-2 hours.

### Examples

Chemicals used in this example were acquired as follows. Potassium sulfide powder (K₂S, anhydrous, min. 95%) was purchased from Strem Chemicals. Tungsten powder (W, PURATRONIC® 99.999% tungsten powder) was purchased from Alfa Aesar. Sulfur powder (S, 99.98%) and potassium dichromate (K₂Cr₂O₇, 99.98%) were purchased from Sigma Aldrich. Sulfuric acid solution (1.0 N) was purchased from LabChem. ITO coated glass slides, square (surface resistivity: 70-100 Ω/sq) were purchased from Sigma Aldrich. PET sheets (2 mm, copolymer), PEN films (0.05 mm, biaxially oriented), Silicone elastomer sheets ((C₂H₆OSi)ₙ) were purchased from GoodFellow Cambridge Limited. Micro cover glass was purchased from VWR. MILLI-QR water, obtained from a MILLI-QR purification system (Millipore Sigma). 2H-WS₂ (nanopowder, 90 nm avg. part. size (SEM), 99% trace metals basis) was purchased from Sigma Aldrich. All the chemicals were used directly without further purification.

### Synthesis of K&WS₂ Crystals

96.0 mg K₂S powder, 320.2 mg W powder, and 83.8 mg S powder were mixed and ground with an agate mortar and pestle in an argon-filled glovebox. Then, the mixture was placed into an alumina crucible (LSP Ceramics) before being sealed in a fused silica ampule (14 mm i.d., 16 mm o.d., Technical Glass Products) under vacuum. The sealed ampule was heated in a furnace to 850° C. in 10 hours and maintained at 850° C. for 24 hours before slowly cooling down to 550° C. at a rate of 3° C./hour. Then, the furnace was turned off to let the ampule cool down to room temperature.

### Chemical Exfoliation of 1T′-WS₂ Monolayers

To exfoliate 1T′-WS₂, the as-synthesized KₓWS₂ crystals were sonicated in 0.5 M H₂SO₄ solution in a 1 mg: 2 mL solid to liquid ratio directly with a Branson 1800 sonicator at low power mode for an hour. After sonication, the upper liquid was transferred to a centrifuge tube for centrifugation at a speed of 12,000 rpm at 4 C for 30 minutes, to replace the solvent with MILLI-QR water. This procedure was repeated twice to remove all the acid. Then, the suspension was sonicated at low power mode with a Branson 1800 sonicator for another hour before being centrifuged at 2000 rpm at 4° C. for 30 minutes. The supernatant containing thin nanosheets was collected, while the sediments containing partially- or un-exfoliated residue were discarded.

### Introduction of Alternate Solvents

1T′-WS₂ nanosheet-powder was collected by centrifuging the aqueous nanosheet suspension at 14000 rpm for 30 minutes to separate the solvent from the nanosheets. The nanosheets were dried under vacuum at room temperature. Then, the dried nanosheet-powder was sonicated in an alternate solvent (here, hexane, methanol, ethanol, IPA, acetone, acetonitrile, DMF, THF, and DMSO), separately, to test their dispersity in different solvents. The nanosheets did not disperse in hexane, methanol, and acetone.

Chemical Exfoliation of 1T-WS, Monolayers from K_{0.5}WS₂

Interstitial water appears if K remains between WS₂ layers. Additionally, the formation of bubbles is observed when crystals of K_{0.5}WS₂ are dispersed into acid. Both phenomena are critical for designing chemical exfoliation methods to delaminate layered materials. Therefore, a route was designed to chemically exfoliate 2M-WS₂ monolayers directly in acid. It was found that direct sonication in either acid successfully delaminates the material, however, the sheets will quickly decompose in HNO₃. If sonicated in H₂SO₄, the sheets remain stable for hours. The sheets may be stable for longer if the acid is replaced by, e.g., water. A stable nanosheet ink in MILLI-QR: water (from Millipore Sigma) with a zeta potential of −57.5±4 mV can be obtained if large unexfoliated pieces are removed via centrifugation at 2000 rpm.

The diluted nanosheet suspension was deposited on a silicon wafer and the sheets were characterized with atomic force microscopy (AFM). The exfoliated 1T′-WS₂ nanosheets have a thickness of about 0.7 nm if measured on top of another nanosheet, which agrees well with the monolayer thickness of 1T′-WS₂. The nanosheet is 1.2 nm thin if measured on the wafer directly, which is a common thickness for chemically exfoliated TMD monolayers on wafers, due to absorbed water molecules. The selected area diffraction (SAED) on a free-standing monolayer can be seen in an AFM image, showing its high crystallinity. The zigzag chains of W atoms of a typical 1T′-TMD structure can be seen in an atomic resolution HAADF-HRSTEM image of a mono-layer and bilayer 1T′-WS₂, and the high quality of the sheet can be seen as it has few visible defects. The chemical composition of the monolayers was confirmed by EDS.

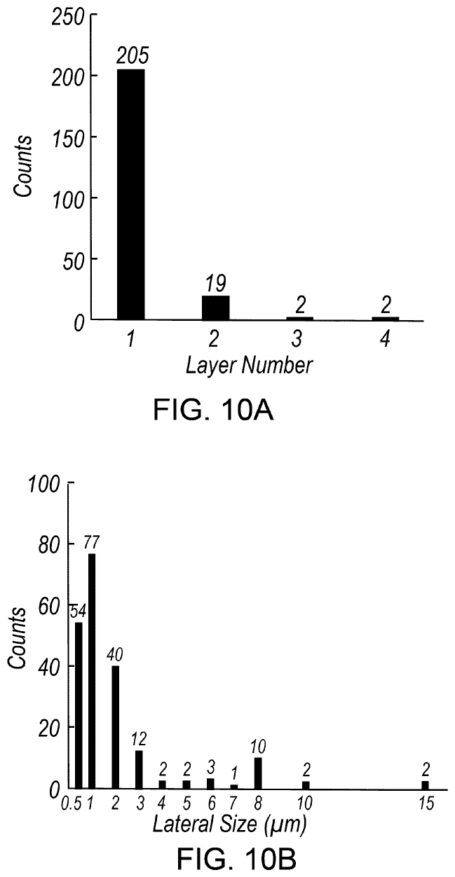

AFM and TEM analysis found that the ink appeared to be almost entirely composed of monolayers and that all larger flakes could be successfully removed with centrifugation as mentioned previously. Specifically, in some embodiments, the exfoliated 1T-WS₂ nanosheets have a thickness of about 0.7 nm if measured on top of another nanosheet, which agrees well with the monolayer thickness of 1T′-WS₂. The nanosheet is 1.2 nm thin if measured on the wafer directly, which is commonly reported for chemically exfoliated TMD monolayers on wafers due to absorbed water molecules. Based on a statistical analysis of more than 200 1T′-WS₂ nanosheets dispersed on a wafer, we found that the vast majority of the exfoliated 1T′-WS₂ nanosheets are monolayers. See FIG. 10A. The median lateral size of the monolayers is about 1 μm. See FIG. 10B. However, larger monolayers with lateral sizes up to 15 μm can also be found easily. As can be seen in TEM images, the 1T′-WS₂ monolayers may randomly stacked on top of each other. The selected area electron diffraction (SAED) on a monolayer 1T′-WS₂ nanosheet confirms its high crystallinity and the 1T′ structure. A few additional diffraction peaks are visible, which arise from the fact that several 1T′-WS₂ monolayers usually lie on top of each other. An atomic resolution scanning transmission electron microscopy (STEM) image of a monolayer 1T′-WS₂ shows no visible defects and impurity phases. More than 50 nanosheets have been analyzed with characterization techniques, such as SAED and high-resolution STEM, and all sheets have been found to be highly crystalline.

AFM and TEM analysis found that the ink seems to be composed of primarily monolayers and that all larger unexfoliated pieces could be successfully removed with centrifugation, as mentioned above. Finally, in order to differentiate these monolayers from their semiconducting 1H counterparts, EELS studies were performed on a monolayer 1T′-WS₂ and a monolayer 1H-WS₂. In the case of 1H-WS₂, features appear around 2, 2.4, and 3 eV, which are the A. B, and C excitons that are associated with the electronic properties of the semiconducting phase, and the broad peak around 8 eV, which corresponds to the 1 plasmon. In contrast, the single-layer 1T′-WS₂ does not exhibit exciton features observed in the 1H-phase: instead, only one broad peak around 6 eV can likely be attributed to a 1 plasmon. This clearly distinguishes the electronic properties of 1T′-WS₂ from its semiconducting 1H counterpart.

Having established the production of an ink made of metallic 1T′-WS₂ monolayers, one can now study its properties. The ink was first deposited and dried on a polymer film. The structure of the dried film was characterized by in-plane PXRD in transmission mode. A 2M-WS₂ crystal was measured in the same way for comparison. The patterns align, suggesting the sheets retained good crystallinity. Two broad peaks appear in addition in the pattern of the ink, these come from some out-of-plane contribution of crumbled sheets in the printed film. The Raman spectrum of the printed 1T′-WS₂ films have the characteristic peaks of the bulk 2M-WS₂ with extra peaks showing up at 196 cm⁻¹ and 400 cm⁻¹, which can be attributed to the loss of symmetry in the monolayers.

To study the electronic transport properties of the 1T′-WS₂ nanosheet-ink, a droplet was deposited on a silicon wafer having pre-patterned gold electrodes. The ink droplet was dried in ambient conditions before Au wires were attached to the exposed pre-patterned electrodes. To gain an insight of how the nanosheets deposit on the wafer, a sample of a dried nanosheet film on a silicon wafer was cut with a focused ion beam (FIB) and studied its cross section with STEM. The film shows that the sheets are in good contact and that the nanosheets randomly stack on top of each other. Even though in some areas, the sheets are crumbled, the majority of the sheets are well-oriented.

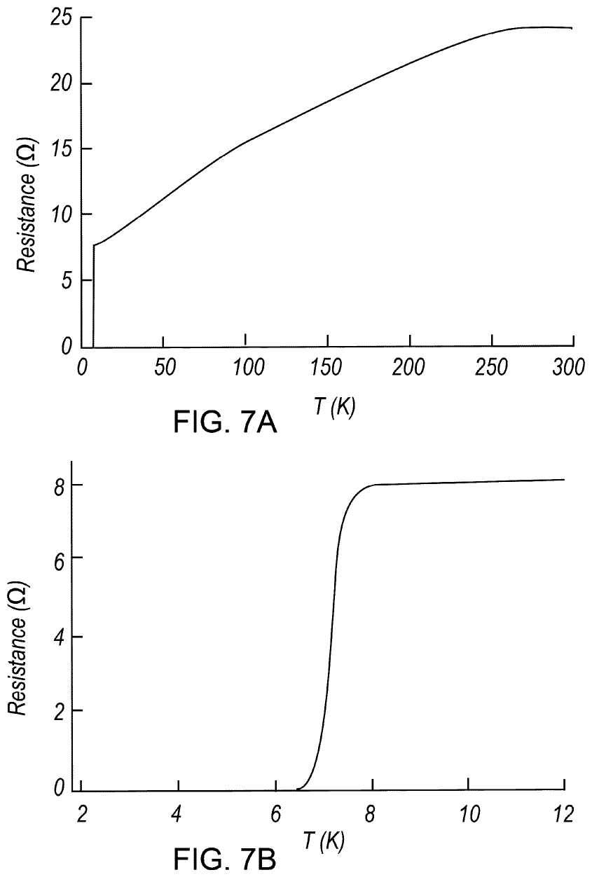

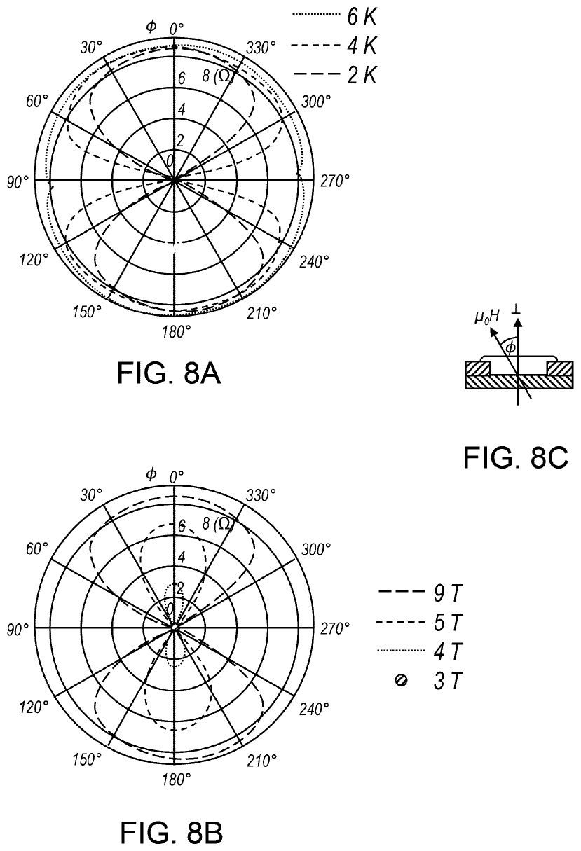

The temperature (T)-dependent resistance in FIGS. 7A and 7B shows that the device is metallic, as the resistance decreases with decreasing temperature. At ˜7.7 K, the resistance drops sharply and reaches zero at ˜6.6 K (See FIG. 7B). The T_{c} is described as the temperature where the resistance drops to 50% of the normal state resistance, which is 7.3 K. As the film is 2D in nature, a strong anisotropy with respect to an applied magnetic field (μ₀H) direction can be expected. The angle-dependent resistance under an applied magnetic field of 9 T at different temperatures is shown in FIG. 8A. Similarly, the angle-dependent resistance at 2 K with different magnetic field strengths is shown in FIG. 8B. The external magnetic field is applied perpendicular to the device plane at ¢=0° and 180° (out-of-plane, μ₀H^{⊥}), and it is parallel to the device plane at ϕ=90° and 270° (in-plane, μ₀H^{∥}) (see FIG. 8C). The electronic transport is highly anisotropic in the superconducting state: it is more easily suppressed when μ₀H^{⊥}, and more robust when μ₀H^{∥} (see FIGS. 8A, 8B). The angle-dependent resistance data shown in FIGS. 8A and 8B suggest that the resistance signal stems predominately from well-orientated nanosheets despite some crumbling.

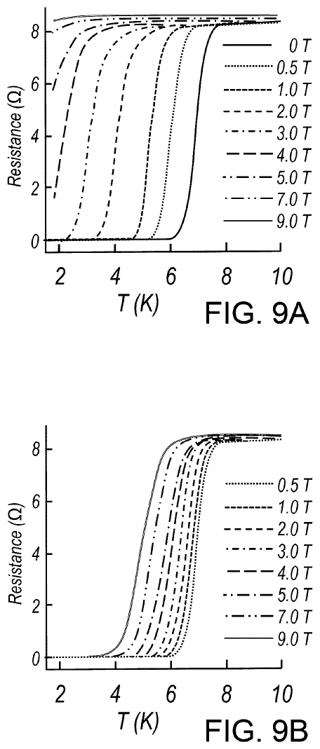

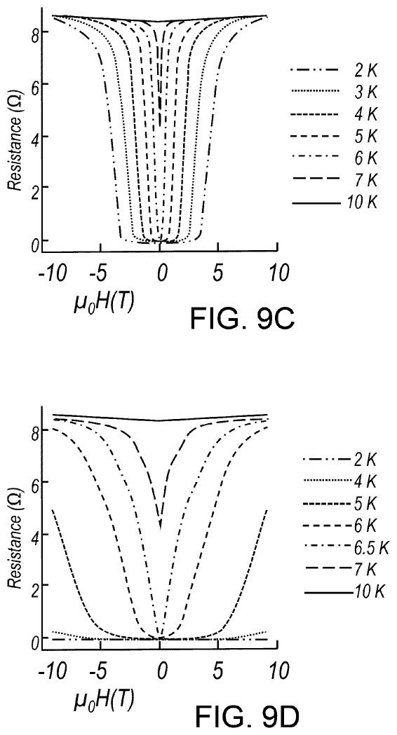

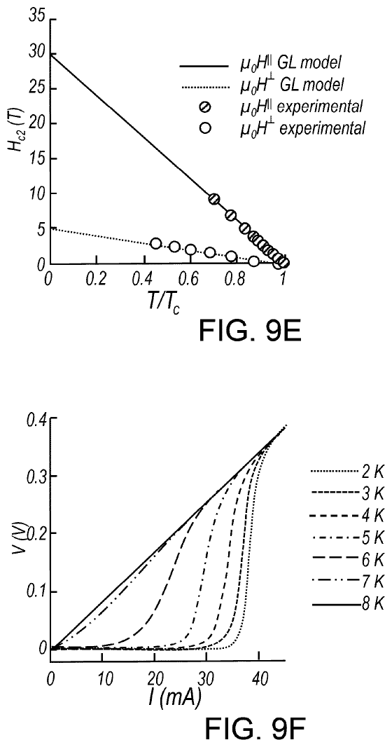

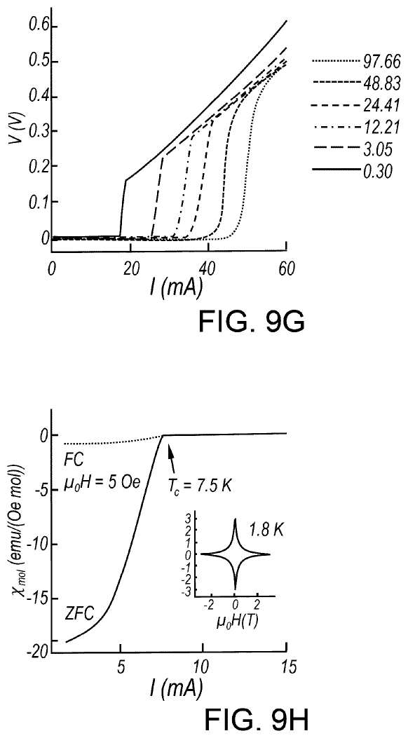

R-T curves were generated at different applied magnetic fields, both with μ₀H^{⊥} and μ₀H^{∥}. Increasing magnetic field strength reduced T_{c}, and the resistance still drops to zero at the highest magnetic field of 9 T if it is applied along the in-plane direction. (see FIGS. 9A-9B) FIGS. 9C-9D show the out-of-plane (R-μ₀H^{⊥} isotherms) and in-plane (R-μ₀H^{∥} isotherms) field-dependent resistance of the printed 1T′-WS₂ film around the transition temperature. Below T_{c}, the R-μ₀H^{⊥} isotherms (FIG. 9C) show a broad transition from the superconducting state to the normal state, and their corresponding critical magnetic field decreases as the temperature increases. When μ₀H is applied parallel to the device plane, below 3 K, the resistance remains zero when the applied magnetic field increases to 9 T, suggesting a very high critical magnetic field when applied parallel to the film. To determine the upper critical magnetic field (H_{c2}), the transition temperature at each applied magnetic field, corresponding to half of its normal state resistance, is plotted vs, the field, for both μ₀H^{⊥} and μ₀H^{∥} (FIG. 9E). A linear correlation of H_{c2} vs. T_{c} can be modelled by the 2D Ginzburg-Landau (GL) theory for both directions:

$${H}_{c 2} ( T ) = \frac{{Φ}_{0}}{2 {πξ}_{GL}^{2} ( 0 )} ( 1 - \frac{T}{{T}_{c}} )$$

where Φ₀ is the magnetic flux quantum, and the ξ_{GL}(0) is the zero-temperature GL in-plane coherence length. This results in an out-of-plane upper critical magnetic field (H_{c2}^{⊥}(0)) of 5.3 T and an in-plane GL superconducting coherence length of ξ_{GL}(0)˜7.9 nm. Fitting the in-plane H_{c2} vs. T_{c} yields an in-plane upper critical magnetic field (H_{c2}(0)) of 30.1 T. Similar to the recently reported printed NbSe₂ film, the H_{c2}^{∥}(0) of the printed 1T′-WS₂ film is very high, far beyond its BCS Pauli paramagnetic limit of 13.1 T (Hₚ˜1.84 T_{c}). However, the symmetry of the centrosymmetric 1T′ structure of WS₂ is fundamentally different from the non-centrosymmetric hexagonal structure of NbSe₂ where Ising type superconductivity is responsible for exceeding the Pauli limit.

The current (I) vs. voltage (V) curves of the device, measured with a fixed alternative current (ac) frequency (24.41 Hz), are shown in FIG. 9F for different temperatures. A critical current (I_{c})˜33 mA can be extracted at 2 K. The critical current decreases with increasing temperature, and the supercurrent eventually disappears at temperatures above T_{c}. When the frequency is varied, as shown in FIG. 9G, the critical current of the printed 1T′-WS₂ film also changes. At 2 K, I_{c} reaches a maximum of ˜44 mA with an excitation current frequency of 97.66 Hz. On the other hand, it decreases to ˜17 mA with the lowest excitation current frequency of 0.30 Hz. The I-V curves become non-linear above I_{c} for all the frequencies as the Joule heating appears.

Next, we studied the de magnetic susceptibility of a re-stacked nanosheet pellet that was collected from the dried ink (FIG. 9H). A strong diamagnetic signal is observed below T_{c}=7.5 K under zero field cooled (ZFC) condition. Field cooling (FC) with an applied magnetic field of 5 Oe suppresses the diamagnetic response due to the Meissner-Ochsenfeld effect. The χₘₒₗ of the nanosheet pellet at 2 K is within the same order of magnitude than bulk 2M-WS₂, thus the majority volume of the restacked sample is superconducting. Both the electronic as well as the magnetic characterizations show that the ink is composed of high-quality superconducting 1T-WS₂ nanosheets that are ready to be used for printing electronics on various substrates.

### Air-Stability

To investigate the air-stability of the 1T′-WS₂ nanosheet-ink and the printed device, the ink and both devices were stored in ambient conditions for a month. A new nanosheet film was printed from the air-exposed ink, and its Raman spectrum is identical to the spectrum from the freshly printed film. The W and S XPS spectra of both films are also identical, suggesting that no oxidation or phase transformation appears when the 1T′-WS₂ nanosheet-ink is stored in ambient atmosphere. The W Spectrum is fitted with one set of W4f doublets with W4f_{7/2} at 31.95 eV and W4f_{5/2} at 34.12 eV, proving that the nanosheets are purely in the 1T′ phase. Temperature-dependent resistance measurements on device 1 after one month of air exposure show that the device has almost the same room temperature resistance, the same residual resistivity ratio (RRR=R_{285K}/R_{8K})˜3, and the T_{c} is almost unchanged as compared to the fresh sample. This is different compared to most other known 2D materials that require preparation in an inert environment and the protection of organic molecules to be handled in air. The 1T′-WS2 nanosheet-ink presented here is robust in water, and is stable in ambient conditions without protection, which gives this ink a higher potential for real-world applications.

### Dispersity in Different Solvents and Printability on Various Substrates.

Finally, it was tested whether an ink could be created with solvents other than water as well as the variety of substrates the ink can be cast on. Common solvents such as hexane, methanol, ethanol, isopropyl alcohol (IPA), acetone, acetonitrile, dimethylformamide (DMF), tetrahydrofuran (THF), and dimethyl sulfoxide (DMSO) were used to disperse the sheets. Among all tested solvents, water gives the best dispersity and highest stability of the 1T′-WS₂ nanosheets.

The aqueous ink was deposited on various substrates, including hard substrates such as SiO₂/Si wafers, borosilicate glass, and ITO coated glass, as well as flexible substrates such as polyethylene terephthalate (PET). Polyethylene naphthalate (PEN), and a silicone elastomer. No obvious cracks or fallen off pieces of the printed patterns were observed while folding the flexible substrates, suggesting a good affinity.

The room-temperature conductivity of the printed nanosheets patterns on the different substrates was measured with a multimeter, showing that each film is metallic at room temperature. Thus, the 1T′-WS₂ monolayer-ink can be prepared with various solvents and can be printed on many different substrates, expanding its possible applications to integrated circuits, and flexible devices.

Thus, the disclosed ink includes nanosheets that are stable in an organic solvent (e.g., water), which provides a cheap, non-toxic and abundant ink-solvent for potential printable superconducting electronics. Exfoliation with high yield is then achieved by sonication, resulting in a suspension composed of monolayers with lateral sizes up to tens of micro-meters, which crystallize in the 1T′-structure. The composition and structure of the products are characterized with multiple diffraction, microscopy and spectroscopy techniques, establishing that the structure remains intact and low in defects, suggesting they are of much higher quality than their mechanical or Li-intercalation exfoliated counterparts. A thin film cast from the nanosheet ink can be superconducting below 7.3 K, with an in-plane upper critical magnetic field of 30.1 T and an out-of-plane upper critical magnetic field of 5.3 T. The film shows highly anisotrpoic superconducting properties, that resemble these observed in gated 1T′-WTe₂ pointing to 2D superconductivity and a potential exotic origin. After exposing the printed film to ambient conditions for 30 days, its electronic transport behavior, as well as its Raman and X-ray photoelectron spectroscopy (XPS) spectra, remain unchanged. Finally, it has been shown that, besides water, the exfoliated 1T′-WS₂ monolayers can be well dispersed in, e.g., several common solvents. The ink forms room-temperature conducting films on various known substrates. Thus, the 1T′-WS₂ monolayer-ink that we present here has a large application range, such as 3D printing, integrated circuits, and flexible devices.

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

What is claimed is:

1. An ink, comprising:
a two-dimensional WS₂ nanosheet; and
a solvent.

2. The ink according to claim 1, wherein the solvent is an organic solvent.

3. The ink according to claim 2, wherein the solvent is water.

4. The ink according to claim 1, wherein the ink is at or below 20° C.

5. The ink according to claim 1, wherein the ink is at or below 7.3 K.

6. An electronic circuit, comprising:
a substrate; and
ink according to claim 1 deposited on a first surface of the substrate to form a pattern.

7. The electronic circuit according to claim 6, wherein the pattern comprises a superconducting qubit.

8. The electronic circuit according to claim 6, wherein the pattern comprises a first portion that is a superconducting portion, and a second portion that has been treated to form a semiconducting portion.

9. The electronic circuit according to claim 6, wherein the substrate is flexible.

10. The electronic circuit according to claim 6, wherein the electronic circuit is at or below 20° C.

11. The electronic circuit according to claim 6, wherein the electronic circuit is at or below 7.3 K.

12. A method for forming a device, comprising:
providing an ink according to claim 1; and
depositing the ink onto a first surface of a substrate.

13. The method according to claim 12, further comprising treating a portion of the ink to form a semiconducting portion.

14. The method according to claim 13, wherein treating a portion of the ink includes heating the ink with a laser or e-beam.

15. The method according to claim 12, wherein the ink is deposited using a 3D printer.

16. The method according to claim 12, further comprising controlling a temperature of the deposited ink to be below 7.3 K.

17. An ink cartridge, comprising:
an ink according to claim 1; and
a housing configured to hold the ink.

18. A method for manufacturing an ink, comprising:
forming a first suspension by sonicating KₓWS₂ and a sulfuric acid solution, where x=0.3˜0.7;
centrifuging the first suspension at a first speed;
forming a WS₂-water suspension by removing any supernatant from the centrifuged first suspension and replacing with water;
sonicating the WS₂-water suspension;
forming the water-based ink by centrifuging the WS₂-water suspension at a second speed, the second speed being less than the first speed, and utilizing an upper portion of a resulting suspension.

19. The method according to claim 18, further comprising forming a WS₂-alternate solvent ink by centrifuging the water-based ink in the presence of an alternate solvent at a third speed, the third speed being higher than the first speed.
